(19) United States
(12) Patent Application Publication
(10) Pub. No.: US 2025/0293196 A1
(43) Pub. Date: Sep. 18, 2025

(54) SEMICONDUCTOR DEVICE AND MANUFACTURING METHOD THEREOF

(71) Applicant: Mitsubishi Electric Corporation, Tokyo (JP)

(72) Inventors: Atsushi ITO, Tokyo (JP); Manabu YOSHINO, Tokyo (JP)

(73) Assignee: Mitsubishi Electric Corporation, Tokyo (JP)

(21) Appl. No.: 18/889,997

(22) Filed: Sep. 19, 2024

(30) Foreign Application Priority Data
Mar. 12, 2024 (JP) 2024-038150

(51) Int. Cl. H01L 23/00; H01L 23/64

(52) U.S. Cl. CPC H01L 24/45; H01L 23/562; H01L 24/03; H01L 24/05; H01L 24/37; H01L 23/645; H01L 2224/03614; H01L 2224/04042; H01L 2224/05551; H01L 2224/05557; H01L 2224/05576; H01L 2224/3702; H01L 2224/4502; H01L 2924/10254; H01L 2924/10272; H01L 2924/1033; H01L 2924/301

(57) ABSTRACT

A method of manufacturing a semiconductor device includes: forming a primary side electrode on a substrate; forming an insulating layer on the substrate and the primary side electrode; forming a secondary side electrode facing the primary side electrode with the insulating layer in between and magnetically or capacitively connected to the primary side electrode on the insulating layer; forming an opening part at the insulating layer by etching to expose part of the primary side electrode; and bonding wiring to the primary side electrode exposed through the insulating layer at the opening part, wherein at least one step is formed on a sidewall of the opening part by performing the etching in a plurality of processes.

### BACKGROUND OF THE INVENTION

### Field

The present disclosure relates to a semiconductor device and a manufacturing method thereof.

### Background

As a coil or a transformer in a semiconductor device, a primary side electrode and a secondary side electrode are magnetically or capacitively connected facing each other with an insulating layer in between. An opening part is formed through the insulating layer, and wiring such as wires is bonded to the primary side electrode exposed through the insulating layer at the opening part (refer to Patent Literature 1, for example).

### CITATION LIST

### Patent Literature

Patent Literature 1: WO 2022/065007

### SUMMARY

### Technical Problem

Conventionally, the opening part has been formed by a single etching process, and the sidewall of the opening part has been substantially vertical with no step formed. Thus, the wiring has needed to be bonded at an angle close to vertical to a semiconductor substrate to avoid contact with the sidewall of the opening part. This has caused a problem with increase in a chip height.

The present disclosure is made to solve the above-described problem and intended to obtain a semiconductor device with a reduced chip height and a manufacturing method thereof.

### Solution to Problem

A semiconductor device according to the present disclosure includes: a substrate; a primary side electrode formed on the substrate; an insulating layer formed on the substrate and the primary side electrode and having an opening part; a secondary side electrode formed on the insulating layer, facing the primary side electrode with the insulating layer in between, and magnetically or capacitively connected to the primary side electrode; and wiring bonded to the primary side electrode exposed through the insulating layer at the opening part, wherein at least one step is formed on a sidewall of the opening part.

A method of manufacturing a semiconductor device according to the present disclosure includes: forming a primary side electrode on a substrate; forming an insulating layer on the substrate and the primary side electrode; forming a secondary side electrode facing the primary side electrode with the insulating layer in between and magnetically or capacitively connected to the primary side electrode on the insulating layer; forming an opening part at the insulating layer by etching to expose part of the primary side electrode; and bonding wiring to the primary side electrode exposed through the insulating layer at the opening part, wherein at least one step is formed on a sidewall of the opening part by performing the etching in a plurality of processes.

### Advantageous Effects of Invention

In the present disclosure, at least one step is formed on the sidewall of the opening part. Accordingly, the angle of the sidewall of the opening part becomes substantially gradual. With this configuration, the distance between the wiring and the upper end of the opening part becomes longer and the extraction angle of the wiring is not restricted. This eliminates necessity for vertically bonding the wiring to the primary side electrode at the opening part and allows increase in the curvature of the wiring. As a result, a reduced chip height can be achieved.

### BRIEF DESCRIPTION OF DRAWINGS

FIG. 1 is a cross-sectional view illustrating a semiconductor device according to a first embodiment.

FIG. 2 is a plan view illustrating the primary side electrode.

FIG. 3 is a plan view illustrating a modification of the primary side electrode.

FIG. 4 is a cross-sectional view illustrating a process of manufacturing the semiconductor device according to the first embodiment.

FIG. 5 is a cross-sectional view illustrating a process of manufacturing the semiconductor device according to the first embodiment.

FIG. 6 is a cross-sectional view illustrating a process of manufacturing the semiconductor device according to the first embodiment.

FIG. 7 is a cross-sectional view illustrating a process of manufacturing the semiconductor device according to the first embodiment.

FIG. 8 is a cross-sectional view illustrating an example of a process of forming an opening part having a step.

FIG. 9 is a cross-sectional view illustrating an example of a process of forming an opening part having a step.

FIG. 10 is a cross-sectional view illustrating another example of a process of forming an opening part having a step.

FIG. 11 is a cross-sectional view illustrating another example of a process of forming an opening part having a step.

FIG. 12 is a cross-sectional view illustrating a modification of an opening part having a step.

FIG. 13 is a cross-sectional view illustrating a modification of an opening part having a step.

FIG. 14 is a cross-sectional view illustrating a modification of the semiconductor device according to the first embodiment.

FIG. 15 is a cross-sectional view illustrating a semiconductor device according to the second embodiment.

FIG. 16 is a cross-sectional view illustrating a process of manufacturing the semiconductor device according to the second embodiment.

FIG. 17 is a cross-sectional view illustrating a semiconductor device according to the third embodiment.

FIG. 18 is a cross-sectional view illustrating a process of manufacturing the semiconductor device according to the third embodiment.

FIG. 19 is a cross-sectional view illustrating a semiconductor device according to the fourth embodiment.

FIG. 20 is a cross-sectional view illustrating a process of manufacturing the semiconductor device according to the fourth embodiment.

### DESCRIPTION OF EMBODIMENTS

A semiconductor device and a manufacturing method thereof according to the embodiments of the present disclosure will be described with reference to the drawings. The same components will be denoted by the same symbols, and the repeated description thereof may be omitted.

### First Embodiment

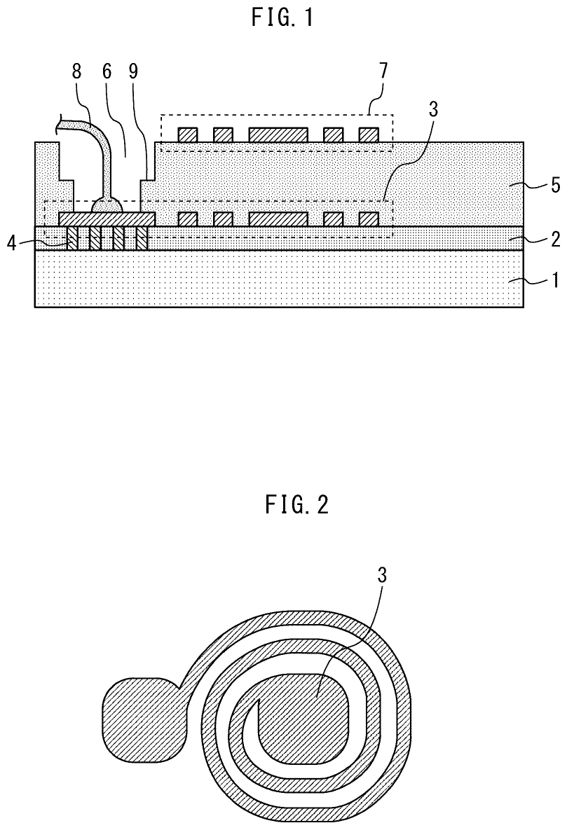

FIG. 1 is a cross-sectional view illustrating a semiconductor device according to a first embodiment. The semiconductor device is a high withstand voltage semiconductor device. A substrate 1 is a semiconductor substrate made of Si, SiC, GaN, or the like or an insulating substrate made of glass, ceramic, or the like. An insulating layer 2 is formed on the substrate 1. The insulating layer 2 is an oxide film or nitride film formed by a typical semiconductor process.

A primary side electrode 3 connected to a first potential is formed on the insulating layer 2. The insulating layer 2 is not necessarily needed in a case where the substrate 1 is an insulating substrate. However, in an actual process, the insulating layer 2 is often formed to improve adhesion with the primary side electrode 3 or with concerns on chemical reactions such as outgassing during pattern formation of the primary side electrode 3. In a case where the substrate 1 is made of semiconductor material, the primary side electrode 3 and a diffusion layer or wiring of the substrate 1 may be connected to each other through a contact 4 penetrating through the insulating layer 2.

An insulating layer 5 is formed on the substrate 1 and the primary side electrode 3. The insulating layer 5 has an opening part 6. Part of the primary side electrode 3 is exposed through the insulating layer 5 at a bottom part of the opening part 6. A secondary side electrode 7 is formed on the insulating layer 5, faces the primary side electrode 3 with the insulating layer 5 in between, and is magnetically or capacitively connected to the primary side electrode 3. The insulating layer 5 holds a desired insulation withstand voltage between the primary side electrode 3 and the secondary side electrode 7. The film thickness of the insulating layer 5 is adjusted in accordance with voltage applied between the primary side electrode 3 and the secondary side electrode 7. The material of the insulating layer 5 is an oxide film, a nitride film, polyimide, or the like.

Wiring 8 such as an aluminum wire is bonded to the primary side electrode 3 exposed through the insulating layer 5 at the opening part 6. At least one step 9 is formed on the sidewall of the opening part 6.

FIG. 2 is a plan view illustrating the primary side electrode. The primary side electrode 3 has a spiral shape, which is the same for the secondary side electrode 7. In this case, the primary side electrode 3 and the secondary side electrode 7 are magnetically connected to each other to perform signal transfer.

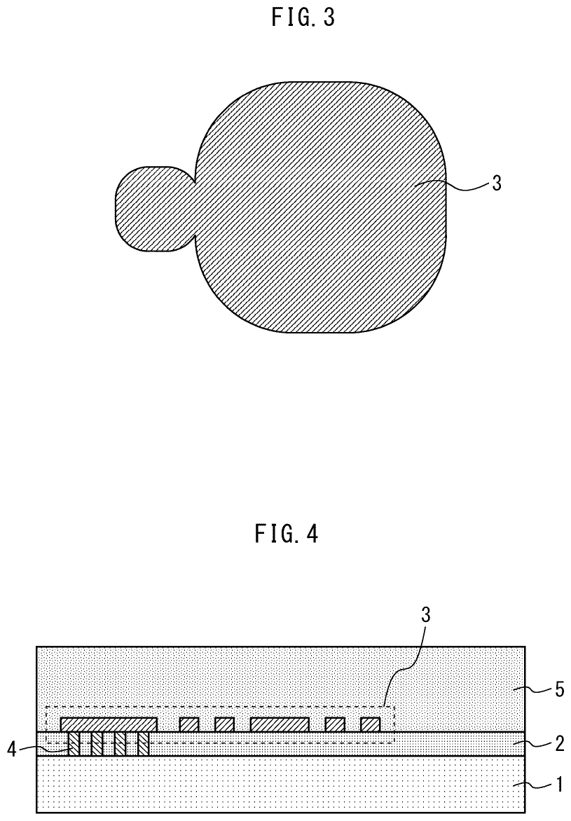

FIG. 3 is a plan view illustrating a modification of the primary side electrode. The primary side electrode 3 has a flat plate shape, which is the same for the secondary side electrode 7. In this case, the primary side electrode 3 and the secondary side electrode 7 are capacitively connected to each other to perform signal transfer.

As described above, mutually facing parts of the primary side electrode 3 and the secondary side electrode 7 have the same shape. Accordingly, the coupling coefficient between the primary side electrode 3 and the secondary side electrode 7 is excellent. However, the diameter of the secondary side electrode 7 may be smaller than the diameter of the primary side electrode 3 to increase surface distance to the primary side electrode 3 exposed at the opening part 6. Accordingly, surface discharge withstand voltage can be improved.

The following describes a method of manufacturing the semiconductor device according to the first embodiment. FIGS. 4 to 7 are cross-sectional views illustrating processes of manufacturing the semiconductor device according to the first embodiment. First, as illustrated in FIG. 4, the insulating layer 2 is formed on the substrate 1, and the primary side electrode 3 is formed on the insulating layer 2. Subsequently, the insulating layer 5 is formed on the insulating layer 2 and the primary side electrode 3.

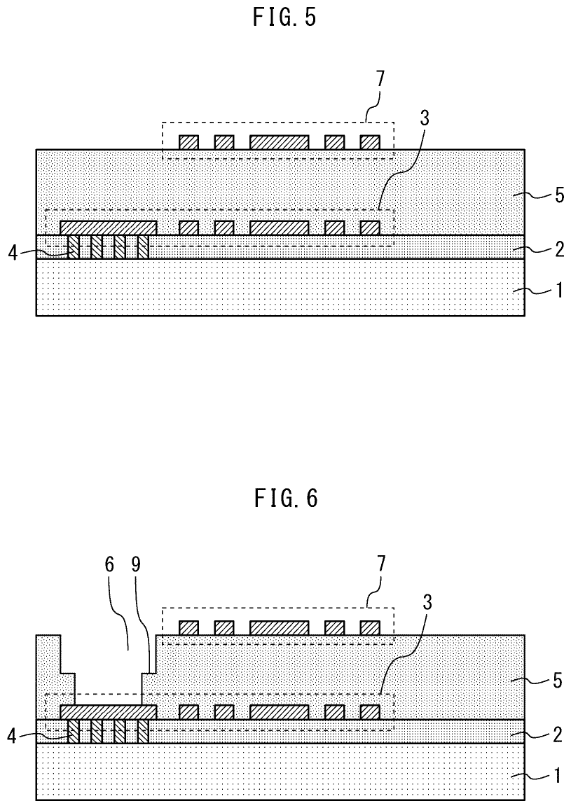

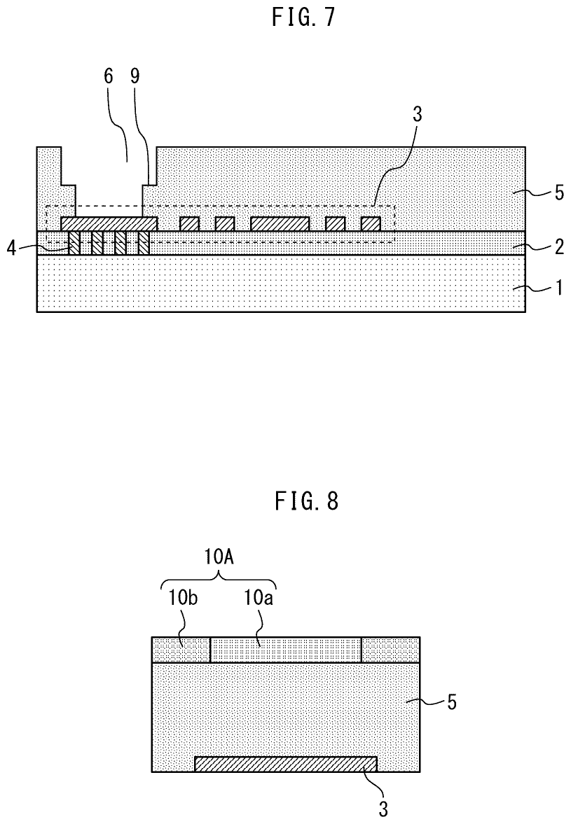

Subsequently, as illustrated in FIG. 5, the secondary side electrode 7 is formed on the insulating layer 5. Subsequently, as illustrated in FIG. 6, the opening part 6 is formed at the insulating layer 5 by etching to expose part of the primary side electrode 3. The etching is performed in a plurality of processes to form at least one step 9 on the sidewall of the opening part 6. In another manufacturing method, after the process of FIG. 4, the opening part 6 may be formed by etching as illustrated in FIG. 7, and thereafter, the secondary side electrode 7 may be formed. Lastly, the wiring 8 is bonded to the primary side electrode 3 exposed through the insulating layer 5 at the opening part 6.

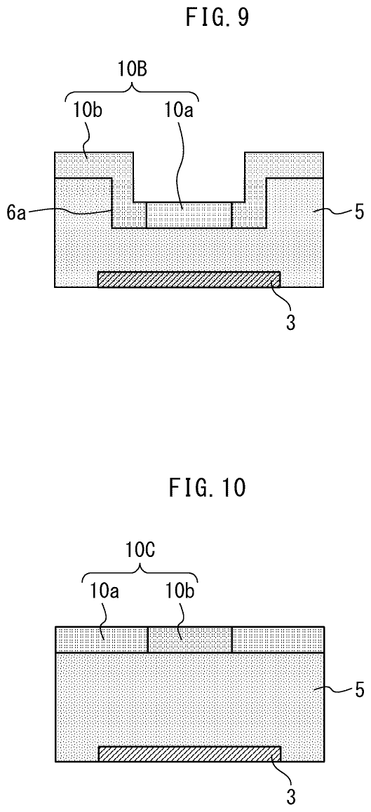

FIGS. 8 and 9 are cross-sectional views illustrating an example of processes of forming an opening part having a step. First, as illustrated in FIG. 8, positive-type photosensitive resist 10A is applied on the insulating layer 5 to expose a place to be etched later. Subsequently, an exposure place 10a is removed by image development and the insulating layer 5 is etched halfway through by using the resist 10A with a non-exposure place 10b remaining as a mask, thereby forming a recessed part 6a. Subsequently, as illustrated in FIG. 9, positive-type photosensitive resist 10B is applied on the insulating layer 5 to expose a place to be etched later. In this process, the exposure place 10a of the resist 10B is formed smaller than the exposure place 10a of the resist 10A. Subsequently, the exposure place 10a is removed by image development and the insulating layer 5 is etched by using the resist 10B with the non-exposure place 10b remaining as a mask until part of the primary side electrode 3 is exposed. In this manner, the opening part 6 including the step 9 can be formed. Since the surface distance is longer as the angle of the sidewall of the step 9 is steeper, it is desirable to use anisotropic etching such as dry etching.

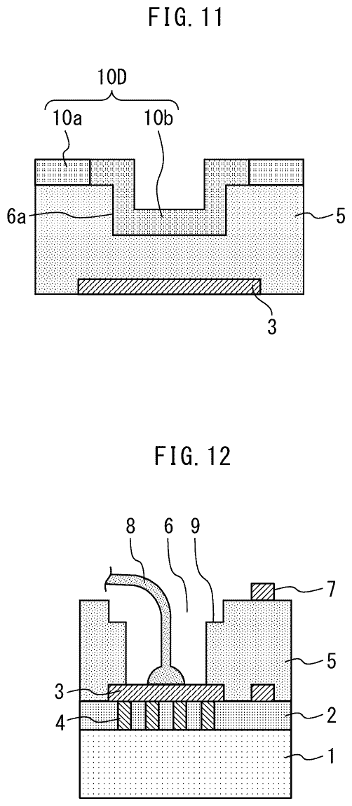

FIGS. 10 and 11 are cross-sectional views illustrating another example of processes of forming an opening part having a step. First, as illustrated in FIG. 10, negative-type photosensitive resist 10C is applied on the insulating layer 5 to expose a place not to be etched later. Subsequently, the non-exposure place 10b is removed by image development and the insulating layer 5 is etched halfway through by using the resist 10C with the exposure place 10a remaining as a mask, thereby forming the recessed part 6a. Subsequently, as illustrated in FIG. 11, negative-type photosensitive resist 10D is applied on the insulating layer 5 to expose a place not to be etched later. In this process, the exposure place 10a of the resist 10D is formed larger than the exposure place 10a of the resist 10C. Subsequently, the non-exposure place 10b is removed by image development and the insulating layer 5 is etched by using the resist 10D with the exposure place 10a remaining as a mask until part of the primary side electrode 3 is exposed. In this manner, the opening part 6 having the step 9 can be formed.

The difficulty of image development increases in a case where photosensitive resist is used in etching and the recessed part 6a exists at an exposure place. Thus, it is needed to adjust the size of the exposure place 10a for the second resist relative to the recessed part 6a as described above.

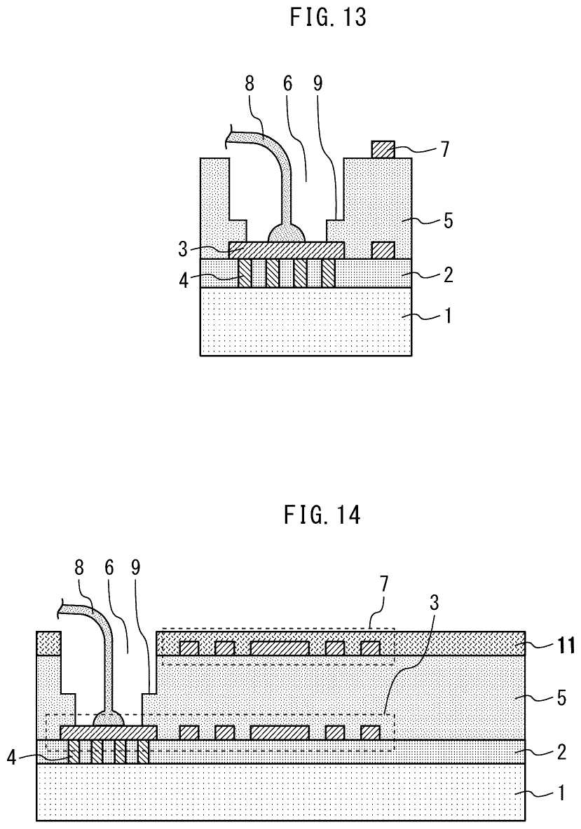

FIGS. 12 and 13 are cross-sectional views illustrating a modification of an opening part having a step. In a case where the height of a lower sidewall of the step 9 is larger than the height of an upper sidewall of the step 9 as in FIG. 12, attention to discharge is needed because of reduction in the distance between the wiring 8 and the upper end of the opening part 6. In a case where the height of the lower sidewall of the step 9 is smaller than the height of the upper sidewall of the step 9 as in FIG. 13, attention to short circuit is needed because of reduction in the distance between the upper surface of the insulating layer 5 and the primary side electrode 3.

As described above, in the present embodiment, the wiring 8 is bonded to the primary side electrode 3 exposed through the insulating layer 5 at the opening part 6. Discharge potentially occurs through the surface of the insulating layer 5 between the wiring 8 and the secondary side electrode 7. Thus, the wiring 8 needs to be formed with sufficient distance from the upper end of the opening part 6. For this, at least one step 9 is formed on the sidewall of the opening part 6. Accordingly, the angle of the sidewall of the opening part 6 becomes substantially gradual. With this configuration, the distance between the wiring 8 and the upper end of the opening part 6 becomes longer and the extraction angle of the wiring 8 is not restricted. This eliminates necessity for vertically bonding the wiring 8 to the primary side electrode 3 at the opening part 6 and allows increase in the curvature of the wiring 8. As a result, a reduced chip height can be achieved.

In a case of a conventional opening part having a vertical sidewall, as well, the curvature of the wiring 8 can be increased by employing a large opening width. With this configuration, the primary side electrode 3 is exposed in a larger area and the surface distance between the primary side electrode 3 and the secondary side electrode 7 is shortened, and as a result, surface discharge voltage decreases. However, in the present embodiment, the opening part 6 can be formed with a small width at a lowermost part, and thus decrease in surface discharge voltage can be prevented.

In the present application, part of the sidewall of the opening part 6 other than the step 9 is vertical. Fabrication of a tapered sidewall has a problem with increase in fabrication time. In particular, in order to achieve a gradual taper angle, it is needed to increase the ratio of etching speed in the horizontal direction to etching speed in the vertical direction, which increases fabrication time.

The wiring 8 is a wire having a curvature in the opening part 6 without contacting the sidewall of the opening part 6. However, the wiring 8 is preferably low-resistance wiring that facilitates flow of current or electric charge for signal transfer between the primary side electrode 3 and the secondary side electrode 7 magnetically or capacitively connected to each other. Thus, a busbar may be used as the wiring 8.

FIG. 14 is a cross-sectional view illustrating a modification of the semiconductor device according to the first embodiment. A surface protective layer 11 is formed on the secondary side electrode 7. Since the surface protective layer 11 covers the secondary side electrode 7, the secondary side electrode 7 can be prevented from contacting non-specific fluid and corrosion of the secondary side electrode 7 can be suppressed. Moreover, for example, in a case where the semiconductor device is molded with resin, it is possible to suppress damage on the secondary side electrode 7 due to a filler contained in the resin. The surface protective layer 11 is also applicable to a second or third embodiment to be described below.

### Second Embodiment

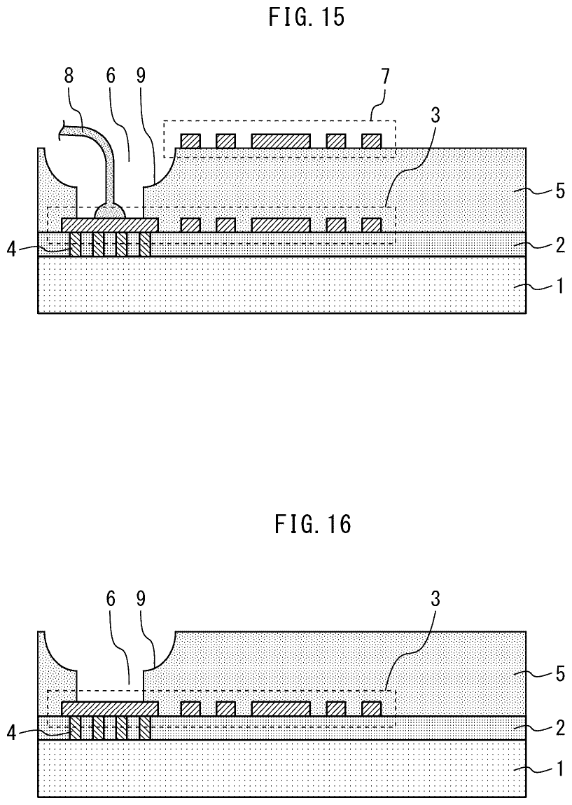

FIG. 15 is a cross-sectional view illustrating a semiconductor device according to the second embodiment. In the present embodiment, the opening part 6 has a circular arc sectional shape at an uppermost part on the upper side of the step 9.

Typically, the secondary side electrode 7 is formed by a photoengraving technology using liquid such as resist and by etching. The arc at the uppermost part of the opening part 6 functions as a slope during, for example, rotational application of resist after formation of the opening part 6. Accordingly, liquid becomes more likely to overflow the upper end part of the opening part 6 and application of liquid such as resist becomes easier. The same effect can be obtained in a case where liquid is further applied to the sectional shape in FIG. 15. The other configurations and effects are the same as in the first embodiment.

The following describes a method of manufacturing the semiconductor device according to the second embodiment. FIG. 16 is a cross-sectional view illustrating a process of manufacturing the semiconductor device according to the second embodiment. Similarly to the first embodiment, the opening part 6 may be formed after the secondary side electrode 7 is formed, or the secondary side electrode 7 may be formed after the opening part 6 is formed. The structure in FIG. 16 is obtained in a case where the opening part 6 is formed first by using etching. The step 9 is formed by performing etching that forms the opening part 6 in a plurality of processes. In order to form the uppermost part of the opening part 6 in a circular arc shape, isotropic etching such as wet etching is used in the first or last process of etching that forms the opening part 6.

### Third Embodiment

FIG. 17 is a cross-sectional view illustrating a semiconductor device according to the third embodiment. In the present embodiment, the opening part 6 has a circular arc sectional shape at a lowermost part lower than the step 9. Since a bottom part corner of the opening part 6 is rounded, liquid such as resist that is rotationally applied after formation of the opening part 6 can be prevented from accumulating at the bottom part corner of the opening part 6. The same effect can be obtained in a case where liquid is further applied to the sectional shape in FIG. 17. The other configurations and effects are the same as in the first embodiment.

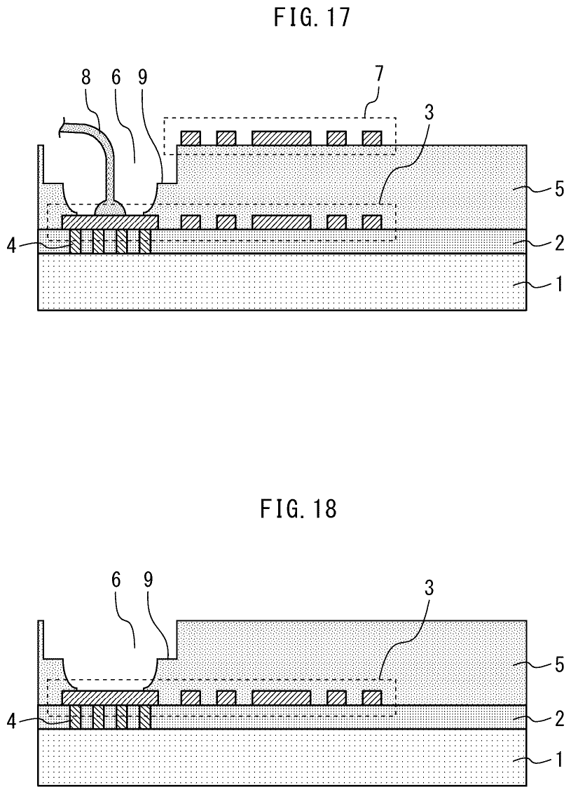

The following describes a method of manufacturing the semiconductor device according to the third embodiment. FIG. 18 is a cross-sectional view illustrating a process of manufacturing the semiconductor device according to the third embodiment. Similarly to the first embodiment, the opening part 6 may be formed after the secondary side electrode 7 is formed, or the secondary side electrode 7 may be formed after the opening part 6 is formed. The structure in FIG. 18 is obtained in a case where the opening part 6 is formed first by using etching. The step 9 is formed by performing etching that forms the opening part 6 in a plurality of process. In order to form the lowermost part of the opening part 6 in a circular arc shape, isotropic etching such as wet etching is used in the first or last process of etching that forms the opening part 6.

### Fourth Embodiment

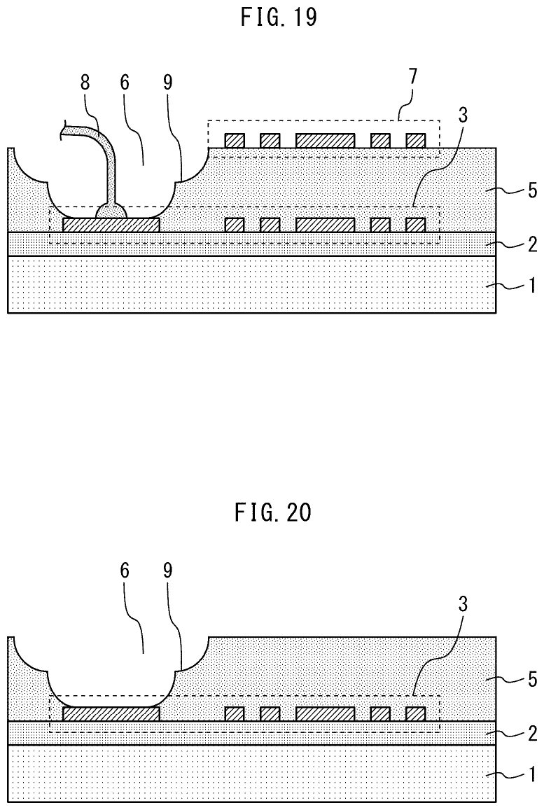

FIG. 19 is a cross-sectional view illustrating a semiconductor device according to the fourth embodiment. In the present embodiment, the opening part 6 has a circular arc sectional shape at an uppermost part on the upper side of the step 9 and has a circular arc sectional shape at a lowermost part on the lower side of the step 9. Accordingly, the effects of both the second and third embodiments can be obtained. The same effects can be obtained in a case where liquid is further applied to the sectional shape in FIG. 19. The other configurations and effects are the same as in the first embodiment.

The following describes a method of manufacturing the semiconductor device according to the fourth embodiment. FIG. 20 is a cross-sectional view illustrating a process of manufacturing the semiconductor device according to the fourth embodiment. Similarly to the first embodiment, the opening part 6 may be formed after the secondary side electrode 7 is formed, or the secondary side electrode 7 may be formed after the opening part 6 is formed. The structure in FIG. 20 is obtained in a case where the opening part 6 is formed first by using etching. The step 9 is formed by performing etching that forms the opening part 6 in a plurality of processes. Isotropic etching such as wet etching is used in a process of etching for forming the circular arc sectional shape during formation of the opening part 6.

The substrate 1 is not limited to a substrate formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor device formed of such a wide-bandgap semiconductor has a high voltage resistance and a high allowable current density, and thus can be miniaturized. The use of such a miniaturized semiconductor device enables the miniaturization and high integration of the semiconductor module in which the semiconductor device is incorporated. Further, since the semiconductor device has a high heat resistance, a radiation fin of a heatsink can be miniaturized and a water-cooled part can be air-cooled, which leads to further miniaturization of the semiconductor module. Further, since the semiconductor device has a low power loss and a high efficiency, a highly efficient semiconductor module can be achieved.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### Supplementary Note 1

A semiconductor device comprising:
a substrate;
a primary side electrode formed on the substrate;
an insulating layer formed on the substrate and the primary side electrode and having an opening part;
a secondary side electrode formed on the insulating layer, facing the primary side electrode with the insulating layer in between, and magnetically or capacitively connected to the primary side electrode; and
wiring bonded to the primary side electrode exposed through the insulating layer at the opening part,
wherein at least one step is formed on a sidewall of the opening part.

### Supplementary Note 2

The semiconductor device according to Supplementary Note 1, wherein a width of the opening part widens in steps from a bottom surface of the insulating layer to a top surface of the insulating layer.

### Supplementary Note 3

The semiconductor device according to Supplementary Note 1 or 2, wherein the wiring is a wire or a busbar having a curvature in the opening part without contacting the sidewall of the opening part.

### Supplementary Note 4

The semiconductor device according to any one of Supplementary Notes 1 to 3, wherein the opening part has a circular arc sectional shape at an uppermost part of the opening part.

### Supplementary Note 5

The semiconductor device according to any one of Supplementary Notes 1 to 4, wherein the opening part has a circular arc sectional shape at a lowermost part of the opening part.

### Supplementary Note 6

The semiconductor device according to any one of Supplementary Notes 1 to 5, further comprising a surface protective layer formed on the secondary side electrode.

### Supplementary Note 7

The semiconductor device according to any one of Supplementary Notes 1 to 6, wherein the substrate is formed of a wide-bandgap semiconductor.

### Supplementary Note 8

A method of manufacturing a semiconductor device comprising:
forming a primary side electrode on a substrate;
forming an insulating layer on the substrate and the primary side electrode;
forming a secondary side electrode facing the primary side electrode with the insulating layer in between and magnetically or capacitively connected to the primary side electrode on the insulating layer;
forming an opening part at the insulating layer by etching to expose part of the primary side electrode; and
bonding wiring to the primary side electrode exposed through the insulating layer at the opening part,
wherein at least one step is formed on a sidewall of the opening part by performing the etching in a plurality of processes.

### Supplementary Note 9

The method of manufacturing a semiconductor device according to Supplementary Note 8, wherein a sectional shape of an uppermost part of the opening part is formed in a circular arc shape by isotropic etching.

### Supplementary Note 10

The method of manufacturing a semiconductor device according to Supplementary Note 8 or 9, wherein a sectional shape of a lowermost part of the opening part is formed in a circular arc shape by isotropic etching.

### REFERENCE SIGNS LIST

1 substrate; 3 primary side electrode; 5 insulating layer; 6 opening part; 7 secondary side electrode; 8 wiring; 9 step; 11 surface protective layer

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2024-038150, filed on Mar. 12, 2024 including specification, claims, drawings and summary, on which the convention priority of the present application is based, is incorporated herein by reference in its entirety.

1. A semiconductor device comprising:
a substrate;
a primary side electrode formed on the substrate;
an insulating layer formed on the substrate and the primary side electrode and having an opening part;
a secondary side electrode formed on the insulating layer, facing the primary side electrode with the insulating layer in between, and magnetically or capacitively connected to the primary side electrode; and
wiring bonded to the primary side electrode exposed through the insulating layer at the opening part,
wherein at least one step is formed on a sidewall of the opening part.

2. The semiconductor device according to claim 1, wherein a width of the opening part widens in steps from a bottom surface of the insulating layer to a top surface of the insulating layer.

3. The semiconductor device according to claim 1, wherein the wiring is a wire or a busbar having a curvature in the opening part without contacting the sidewall of the opening part.

4. The semiconductor device according to claim 1, wherein the opening part has a circular arc sectional shape at an uppermost part of the opening part.

5. The semiconductor device according to claim 1, wherein the opening part has a circular arc sectional shape at a lowermost part of the opening part.

6. The semiconductor device according to claim 1, further comprising a surface protective layer formed on the secondary side electrode.

7. The semiconductor device according to claim 1, wherein the substrate is formed of a wide-bandgap semiconductor.

8. A method of manufacturing a semiconductor device comprising:
forming a primary side electrode on a substrate;
forming an insulating layer on the substrate and the primary side electrode;
forming a secondary side electrode facing the primary side electrode with the insulating layer in between and magnetically or capacitively connected to the primary side electrode on the insulating layer;
forming an opening part at the insulating layer by etching to expose part of the primary side electrode; and
bonding wiring to the primary side electrode exposed through the insulating layer at the opening part,
wherein at least one step is formed on a sidewall of the opening part by performing the etching in a plurality of processes.

9. The method of manufacturing a semiconductor device according to claim 8, wherein a sectional shape of an uppermost part of the opening part is formed in a circular arc shape by isotropic etching.

10. The method of manufacturing a semiconductor device according to claim 8, wherein a sectional shape of a lowermost part of the opening part is formed in a circular arc shape by isotropic etching.
